(19) United States
(12) Patent Application Publication
(10) Pub. No.: US 2024/0258209 A1
(43) Pub. Date: Aug. 1, 2024

(54) SEMICONDUCTOR DEVICE

(71) Applicant: Mitsubishi Electric Corporation, Tokyo (JP)

(72) Inventor: Kazuo FUNAHASHI, Tokyo (JP)

(73) Assignee: Mitsubishi Electric Corporation, Tokyo (JP)

(21) Appl. No.: 18/499,699

(22) Filed: Nov. 1, 2023

(30) Foreign Application Priority Data
Jan. 26, 2023 (JP) 2023-010141

(51) Int. Cl. H01L 23/495

(52) U.S. Cl. CPC H01L 23/49537; H01L 23/49558; H01L 23/49568

(57) ABSTRACT

A semiconductor device includes: a plurality of lead frames; a plurality of semiconductor elements mounted to the plurality of lead frames; a heat sink disposed below the plurality of lead frames; and an insulating sheet interposed between the plurality of lead frames and the heat sink. The insulating sheet and the heat sink are each divided into two or more portions, and all the plurality of semiconductor elements are arranged at positions overlapping the insulating sheet and the heat sink in plan view.

### BACKGROUND OF THE INVENTION

### Field of the Invention

The present disclosure relates to semiconductor devices and, in particular, to a semiconductor device including an insulating sheet at a heat dissipating surface.

### Description of the Background Art

A semiconductor device having a structure in which a highly heat dissipating insulating sheet is interposed between a lead frame to which a semiconductor element is mounted and a heat sink to insulate the lead frame and the heat sink from each other is known. For example, Japanese Patent Application Laid-Open No. 2018-82005 discloses a semiconductor device having a structure in which a lead frame to which semiconductor elements are mounted includes thick portions and thin portions, insulating sheets are bonded to lower surfaces of the thick portions, and separate insulating sheets are bonded to adjacent thick portions.

In the manufacture of a semiconductor device, components of the semiconductor device thermally shrink in the course of reducing the temperature to room temperature after sealing of the semiconductor device with a molding resin. In particular, an increase in size of the semiconductor device leads to an increase in amount of deformation of the components due to thermal shrinkage, making a failure such as breakage and separation of an insulating sheet likely to occur.

### SUMMARY

It is an object of the present disclosure to provide a semiconductor device capable of preventing breakage and separation of an insulating sheet.

A semiconductor device according to the present disclosure includes: a plurality of lead frames; a plurality of semiconductor elements mounted to the plurality of lead frames; a heat sink disposed below the plurality of lead frames; and an insulating sheet interposed between the plurality of lead frames and the heat sink. The insulating sheet and the heat sink are each divided into two or more portions. All the plurality of semiconductor elements are arranged at positions overlapping the insulating sheet and the heat sink in plan view.

According to the present disclosure, an effect of preventing breakage and separation of the insulating sheet can be obtained.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a configuration of a semiconductor device according to Embodiment 1;

FIG. 2 is a diagram illustrating an example of the semiconductor device as a semifinished product after molding with a molding resin;

FIG. 3 is a diagram illustrating an example of the semiconductor device after processing of lead frames;

FIG. 4 is a diagram for explaining a method illustrated in the present disclosure;

FIG. 5 is a diagram illustrating a configuration of a semiconductor device according to Embodiment 2; and

FIG. 6 is a diagram illustrating a configuration of a semiconductor device according to Embodiment 3.

### DESCRIPTION OF THE PREFERRED EMBODIMENTS

### Embodiment 1

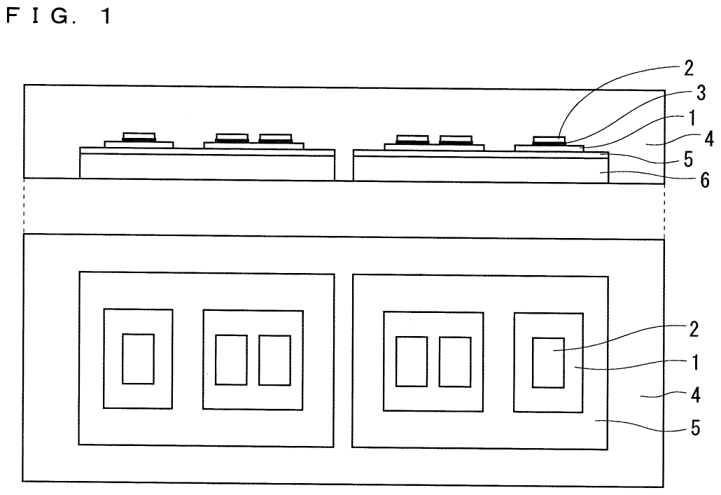

FIG. 1 is a diagram illustrating a configuration of a semiconductor device according to Embodiment 1. The semiconductor device according to Embodiment 1 includes a plurality of lead frames 1 formed of metal, such as copper, and a plurality of semiconductor elements 2 as semiconductor chips mounted to the plurality of lead frames 1. The lead frames 1 and the semiconductor elements 2 are bonded via bonding agents 3. As will be described below, the lead frames 1 are only partially illustrated in FIG. 1. Electrodes arranged on upper surfaces of the semiconductor elements 2 are electrically connected using metal wires and the like but are not illustrated.

A highly heat dissipating insulating sheet 5 formed of a mixture of a resin and an inorganic filler, for example, is disposed on lower surfaces of the lead frames 1, and a heat sink 6 formed of metal is disposed below the insulating sheet 5. That is to say, the heat sink 6 is affixed to the lead frames 1 via the insulating sheet 5, and the insulating sheet 5 insulates the lead frames 1 and the heat sink 6 from each other.

The lead frames 1 to which the semiconductor elements 2, the insulating sheet 5, and the heat sink 6 are bonded are sealed with a molding resin 4 formed of a mixture of a resin and an inorganic filler, for example. A lower surface of the heat sink 6 is exposed from the molding resin 4 to be a heat dissipating surface (a surface to which an external cooler is attached) of the semiconductor device. In a plan view shown in FIG. 1, the molding resin 4 is made transparent to illustrate arrangement of the lead frames 1, the semiconductor elements 2, and the insulating sheet 5. The same applies to the other plan views shown below.

The insulating sheet 5 and the heat sink 6 are each divided into two or more portions inside the semiconductor device. The two or more portions of the insulating sheet 5 are not in contact with each other, and, similarly, the two or more portions of the heat sink 6 are not in contact with each other. That is to say, there are gaps between the portions of the insulating sheet 5 and between the portions of the heat sink 6, and the gaps are filled with the molding resin 4. The portions of the insulating sheet 5 each have no deficit, such as a hole and a slit, therein and are uniformly formed in plan view.

All the plurality of semiconductor elements 2 are arranged at positions overlapping the insulating sheet 5 and the heat sink 6 in plan view. That is to say, in all the portions overlapping the semiconductor elements 2, the lead frames 1 are in intimate contact with the insulating sheet 5.

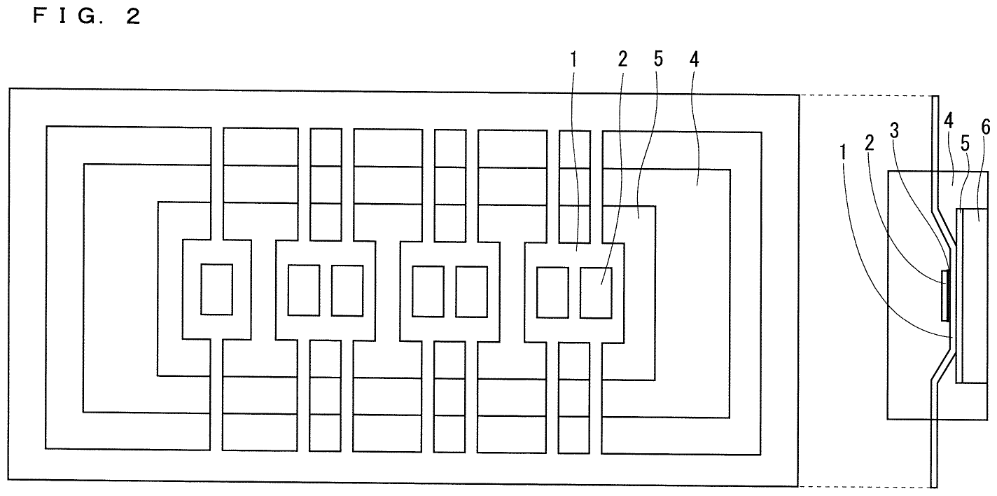

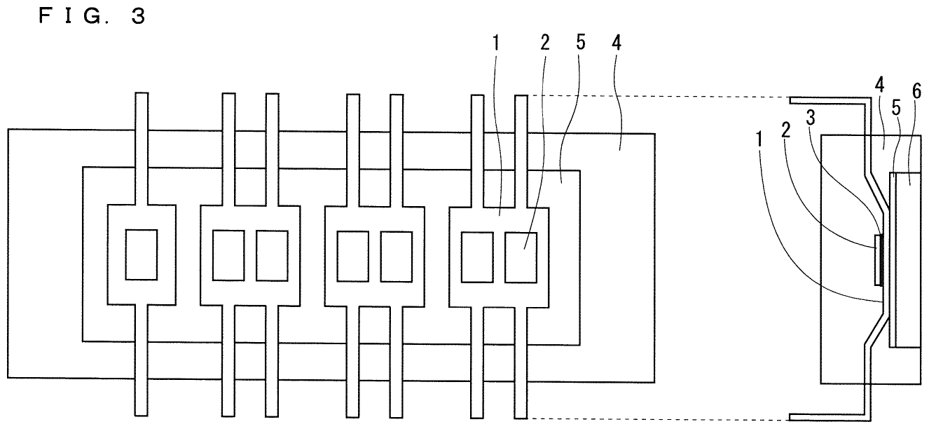

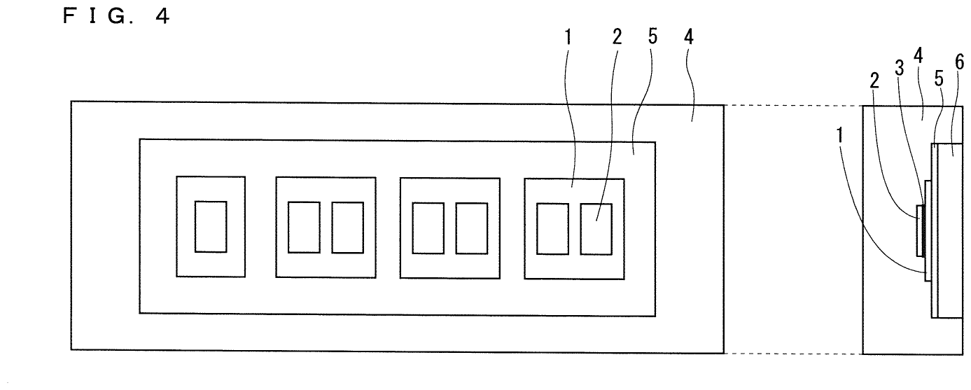

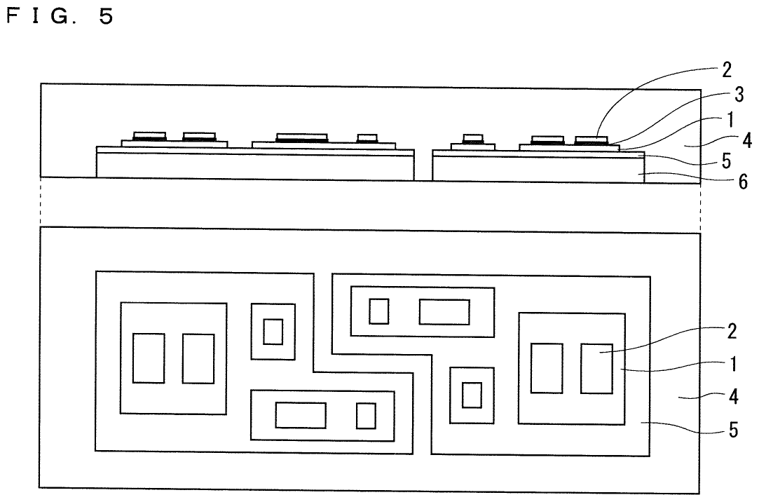

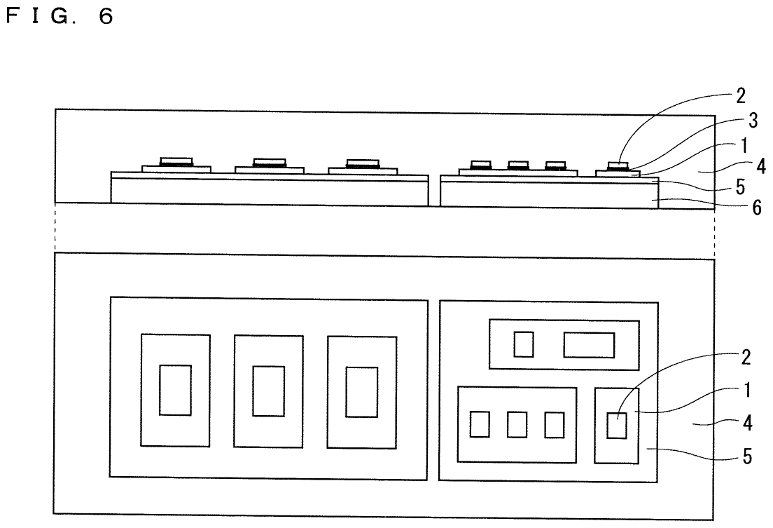

The semiconductor device as a semifinished product during molding with the molding resin 4 is herein illustrated in FIG. 2. During molding with the molding resin 4, the lead frames 1 are connected together outside the molding resin 4. In a subsequent frame processing step, a frame portion at an outer periphery of the connected lead frames 1 is cut off to divide the connected lead frames 1 into the plurality of lead frames 1 as illustrated in FIG. 3. In contrast to FIG. 3, portions of the lead frames 1 not being in intimate contact with the insulating sheet 5 are not illustrated in FIG. 4. The portions of the lead frames 1 not being in intimate contact with the insulating sheet 5 are not illustrated in FIG. 1 as in FIG. 4. The same applies to FIGS. 5 and 6 shown below.

In an example of FIG. 1, the insulating sheet 5 and the heat sink 6 are each divided into two portions, and the two portions of the insulating sheet 5 and the two portions of the heat sink 6 are arranged point symmetrically by 180° with respect to the center of the semiconductor device in plan view. Two or more lead frames 1 are in intimate contact with one portion of the insulating sheet 5, and the plurality of semiconductor elements 2 are arranged over one portion of the insulating sheet 5.

According to the semiconductor device according to Embodiment 1, the insulating sheet 5 is divided into two or more portions, so that thermal stress applied to the insulating sheet 5 is reduced to prevent breakage and separation of the insulating sheet 5. For example, when the insulating sheet 5 is divided into two portions, stress (separating stress) acting to separate the insulating sheet 5 is approximately halved. In addition, dividing into the plurality of lead frames 1 can relieve internal stress applied by a long-term reliability test, such as a thermal cycling test, to eliminate one of factors for separation of the insulating sheet 5.

Furthermore, all the plurality of semiconductor elements 2 are arranged at positions overlapping the insulating sheet 5 and the heat sink 6 in plan view, so that high heat dissipation can be secured to suppress reduction in heat dissipation caused by dividing each of the insulating sheet 5 and the heat sink 6 into two or more portions.

The two or more portions of the insulating sheet 5 are point symmetrically arranged, so that the plurality of portions of the insulating sheet 5 having the same shape can be used for one semiconductor device. Productivity and component cost can thereby be maintained to substantially the same degree as before.

### Embodiment 2

FIG. 5 is a diagram illustrating a configuration of a semiconductor device according to Embodiment 2. A basic configuration of the semiconductor device according to Embodiment 2 is the same as that according to Embodiment 1.

While each of the portions of the insulating sheet 5 and the portions of the heat sink 6 has a simple rectangular shape in plan view in Embodiment 1, each of the portions of the insulating sheet 5 and the portions of the heat sink 6 has a shape (herein, a L-shape) conforming to arrangement of the lead frames 1 in plan view in Embodiment 2. As in Embodiment 1, two portions of the insulating sheet 5 and two portions of the heat sink 6 are point symmetrically arranged with respect to the center of the semiconductor device in plan view.

According to the semiconductor device according to Embodiment 2, not only an effect similar to that obtained in Embodiment 1 but also an effect of reducing the area of each of the portions of the insulating sheet 5 and the portions of the heat sink 6 to contribute to miniaturization and densification of the semiconductor device can be obtained.

### Embodiment 3

FIG. 6 is a diagram illustrating a configuration of a semiconductor device according to Embodiment 3. A basic configuration of the semiconductor device according to Embodiment 3 is the same as that according to Embodiment 1.

Each of the portions of the insulating sheet 5 and the portions of the heat sink 6 has the shape conforming to arrangement of the lead frames 1 in plan view also in Embodiment 3, but, as a result, the portions of the insulating sheet 5 and the portions of the heat sink 6 are asymmetrically arranged in plan view.

In the semiconductor device according to Embodiment 3, it is necessary to prepare portions of the insulating sheet 5 having different shapes, but, if the number of types of the shapes of the portions of the insulating sheet 5 is approximately two, productivity can be maintained to substantially the same degree as that in Embodiments 1 and 2. Component cost, however, is slightly higher than that in Embodiment 2.

Eliminating constraints on point symmetrical arrangement of the portions of the insulating sheet 5 and the portions of the heat sink 6 produces an effect of increasing flexibility of arrangement of the semiconductor elements 2 and the lead frames 1 and further reducing the area of each of the portions of the insulating sheet 5 and the portions of the heat sink 6.

### Embodiment 4

A configuration of a semiconductor device according to Embodiment 4 is the same as that in Embodiment 3. While two portions of the insulating sheet 5 have different shapes in Embodiment 3, the two portions of the insulating sheet 5 further have different thermal conductivities in Embodiment 4. Thermal conductivities of the respective two or more portions of the insulating sheet 5 are determined from current-carrying capacities, arrangement, and the like of the semiconductor elements 2 mounted thereto in view of required heat dissipating properties. The two portions of the insulating sheet 5 may have the same thermal conductivity as a result of determination.

According to Embodiment 4, the number of options for a material for the insulating sheet 5 increases. For example, selecting an inexpensive insulating sheet 5 having a low thermal conductivity can reduce the component cost and contribute to reduction in cost of the semiconductor device. Embodiment 4 may be applied to the insulating sheet 5 (the portions of the insulating sheet 5 having the same shape) according to Embodiment 1 or 2.

Embodiments can freely be combined with each other and can be modified or omitted as appropriate.

### <Appendices>

Various aspects of the present disclosure will collectively be described below as appendices.

### (Appendix 1)

A semiconductor device comprising:
a plurality of lead frames;
a plurality of semiconductor elements mounted to the plurality of lead frames;
a heat sink disposed below the plurality of lead frames; and
an insulating sheet interposed between the plurality of lead frames and the heat sink, wherein
the insulating sheet and the heat sink are each divided into two or more portions, and
all the plurality of semiconductor elements are arranged at positions overlapping the insulating sheet and the heat sink in plan view.

### (Appendix 2)

The semiconductor device according to Appendix 1, wherein
the two or more portions of the insulating sheet have different thermal conductivities.

### (Appendix 3)

The semiconductor device according to Appendix 1 or 2, wherein
two or more lead frames are in intimate contact with one portion of the insulating sheet.

### (Appendix 4)

The semiconductor device according to any one of Appendices 1 to 3, wherein
the two or more portions of the insulating sheet have shapes corresponding to arrangement of the plurality of lead frames.

### (Appendix 5)

The semiconductor device according to any one of Appendices 1 to 4, wherein
the two or more portions of the insulating sheet are point symmetrically arranged in plan view.

### (Appendix 6)

The semiconductor device according to any one of Appendices 1 to 4, wherein
the two or more portions of the insulating sheet are asymmetrically arranged in plan view.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a plurality of lead frames;
a plurality of semiconductor elements mounted to the plurality of lead frames;
a heat sink disposed below the plurality of lead frames; and
an insulating sheet interposed between the plurality of lead frames and the heat sink, wherein
the insulating sheet and the heat sink are each divided into two or more portions, and
all the plurality of semiconductor elements are arranged at positions overlapping the insulating sheet and the heat sink in plan view.

2. The semiconductor device according to claim 1, wherein
the two or more portions of the insulating sheet have different thermal conductivities.

3. The semiconductor device according to claim 1, wherein
two or more lead frames are in intimate contact with one portion of the insulating sheet.

4. The semiconductor device according to claim 2, wherein
two or more lead frames are in intimate contact with one portion of the insulating sheet.

5. The semiconductor device according to claim 1, wherein
the two or more portions of the insulating sheet have shapes corresponding to arrangement of the plurality of lead frames.

6. The semiconductor device according to claim 2, wherein
the two or more portions of the insulating sheet have shapes corresponding to arrangement of the plurality of lead frames.

7. The semiconductor device according to claim 1, wherein
the two or more portions of the insulating sheet are point symmetrically arranged in plan view.

8. The semiconductor device according to claim 2, wherein
the two or more portions of the insulating sheet are point symmetrically arranged in plan view.

9. The semiconductor device according to claim 1, wherein
the two or more portions of the insulating sheet are asymmetrically arranged in plan view.

10. The semiconductor device according to claim 2, wherein
the two or more portions of the insulating sheet are asymmetrically arranged in plan view.
